(19) United States
(12) Patent Application Publication
(10) Pub. No.: US 2026/0290922 A1
(43) Pub. Date: Sep. 24, 2026

(54) BATTERY-PACK DIAGNOSTIC SYSTEM FOR VEHICLES

(71) Applicant: POEN Co., Ltd., Uiwang-si (KR)

(72) Inventor: Dong Min YEO, Anseong-si (KR)

(21) Appl. No.: 19/388,119

(22) Filed: Nov. 13, 2025

(30) Foreign Application Priority Data
Mar. 24, 2025 (KR) 10-2025-0037381

(51) Int. Cl. H01M 10/48; B60L 3/00; B60L 58/12; B60L 58/16; G08B 21/18; H01M 10/42

(52) U.S. Cl. CPC H01M 10/488; B60L 3/0046; B60L 58/12; B60L 58/16; G08B 21/182; G08B 21/185; H01M 10/425; H01M 10/4285; H01M 10/486; B60L 2240/12; B60L 2240/545; B60L 2240/547; H01M 2010/4271; H01M 2010/4278

(57) ABSTRACT

An embodiment relates to provide a vehicle battery pack diagnostic system that enables the separation of a battery module installed in a scrapped electric vehicle and allows for detection of various current states of the separated battery module based on multiple devices, while overcoming the problems of complicated cable connections and limited portability that occur during vehicle battery diagnosis. Based on such detection, the system is configured to operate in a manner that enables the reuse of the battery module.

### CROSS REFERENCE TO RELATED APPLICATION

The present application claims priority to Korean Patent Application No. 10-2025-0037381, filed Mar. 24, 2025, the entire contents of which are incorporated herein for all purposes by this reference.

### BACKGROUND

### Technical Field

The invention relates to a battery pack diagnostic system for vehicles.

### Description of the Related Art

Recently, with the growing demand for electric vehicles, various battery development efforts have been undertaken, and many patents have been filed regarding battery life and its verification. In particular, diagnosing vehicle batteries or detachable batteries currently requires several types of cables.

Conventionally, cables for power supply, CAN communication or CANFD communication, and additional connectors for data transmission and reception have been required. However, in conventional systems, since multiple cables must be connected and managed through complicated connection work, there are problems such as increased work time and reduced efficiency. Moreover, due to poor portability, multiple cables and devices must be carried simultaneously, which limits the mobility of inspection equipment. Additionally, because of the large number of physical connections, problems such as cable damage or data transmission errors caused by incorrect connections may occur.

Accordingly, there is a need for a device and/or system that can easily obtain various data from a battery module using a portable device structure and notify internal and external systems of any detected issues, thereby overcoming the above-mentioned problems.

### SUMMARY

The technical problem to be solved by the present invention has been created to address the aforementioned issues. Specifically, the invention aims to provide a vehicle battery pack diagnostic system that enables the separation of a battery module installed in a scrapped electric vehicle and allows for detection of various current states of the separated battery module based on multiple devices, while overcoming the problems of complicated cable connections and limited portability that occur during vehicle battery diagnosis. Based on such detection, the system is configured to operate in a manner that enables the reuse of the battery module.

According to various embodiments, a vehicle battery pack diagnostic system includes: a battery module installed inside an electric vehicle and including at least one battery therein; a housing that accommodates the battery module and includes a switch and a display on its outer upper surface; at least one sensing module installed inside the housing and configured to detect a state of the battery module; a battery management system (BMS) module installed inside the housing, configured to output a first warning message data related to charging of the battery module when temperature data of the battery module detected by the at least one sensing module exceeds a preset first temperature threshold, and to output a second warning message data related to charging of the battery module when voltage data of the battery module detected by the at least one sensing module exceeds a preset first voltage threshold; a wireless communication module movably coupled to one end of the upper portion of the housing, configured to receive a control signal from an external source for the battery management system module, to transmit data for managing the battery management system module to the outside, and to communicate through a short-range wireless communication method using BLE (Bluetooth Low Energy); and a communication connector module connected to the other end of the upper portion of the housing and configured to enable CAN (Controller Area Network) communication between the battery management system module and the vehicle ECU (Electronic Control Unit).

According to various embodiments, the at least one sensing module may include: a state sensor configured to detect the State of Charge (SOC) and State of Health (SOH) of the battery module; a voltmeter configured to detect the voltage of the battery and the battery module; a temperature sensor configured to detect the temperature of the battery module; and a speed sensor configured to detect the driving history values associated with the battery module.

According to various embodiments, the battery management system (BMS) module is configured such that: when the temperature data of the battery module is determined to be equal to or higher than a first temperature threshold and equal to or lower than a second temperature threshold that is set higher than the first threshold, the BMS module outputs a first warning message data; and when the temperature data of the battery module is determined to be equal to or higher than both the first and second temperature thresholds, the BMS module outputs a first danger message data—representing a more critical stage than the first warning message—through at least one output module, while blocking the charging of the battery module.

According to various embodiments, the battery management system module is also configured such that: when the temperature data of the battery module is determined to be equal to or lower than a third temperature threshold—which is set below the first temperature threshold—and equal to or higher than a fourth temperature threshold—which is set below the third threshold—the module outputs a first-1 warning message data through at least one output module; and when the temperature data of the battery module is determined to be equal to or lower than both the third and fourth temperature thresholds, the module outputs a first-1 danger message data, representing a more severe stage than the first-1 warning message, through at least one output module, while blocking both charging and discharging of the battery module.

According to various embodiments, the battery management system module is further configured such that: when the voltage data of the battery module is determined to be equal to or higher than a first voltage threshold and equal to or lower than a second voltage threshold that is set higher than the first threshold, the module outputs a second warning message data through at least one output module; and when the voltage data of the battery module is determined to be equal to or higher than both the first and second voltage thresholds, the module outputs a second danger message data—representing a more critical stage than the second warning message—through at least one output module, while blocking the charging of the battery module.

According to the present embodiment, the battery pack diagnostic system detects the condition and real-time charging status of a battery module—separated from a scrapped electric vehicle—based on at least one sensing module connected to the battery management system module. Based on the detected data, it is possible to determine in advance whether the battery module can be reused or if failures are likely to occur. Furthermore, during the diagnosis of the battery module, cable connections can be minimized or replaced with wireless connections, thereby shortening inspection time, improving portability, and preventing data loss or errors caused by connection faults.

According to additional embodiments, the battery management system (BMS) module is configured such that: when the voltage data of the battery module is determined to be equal to or lower than a third voltage threshold, which is set below the first voltage threshold, and equal to or higher than a fourth voltage threshold, which is set below the third threshold, the module outputs a second-1 warning message data through at least one output module; and when the voltage data of the battery module is determined to be equal to or lower than both the third and fourth voltage thresholds, the module outputs a second-1 danger message data—representing a more critical stage than the second-1 warning message—through at least one output module, while blocking both charging and discharging of the battery module.

According to additional embodiments, the battery management system module performs encryption and decryption of at least one output data set using a preset symmetric key, and the communication connector module is configured to: compare a checksum and a sequence number included in a data frame of the encrypted and decrypted output data received through the wireless communication module with a preset error threshold; and determine that the output data contains an error value when the comparison result exceeds the error threshold.

### BRIEF DESCRIPTION OF THE DRAWINGS

FIG. 1 is a block diagram illustrating the diagnostic structure for a battery module installed in a vehicle according to various embodiments of the present invention.

FIG. 2 is an overall view illustrating the battery module installed in a vehicle according to various embodiments of the present invention.

FIG. 3 is a structural diagram illustrating an example of the battery module installed in a vehicle according to various embodiments of the present invention.

FIG. 4 is a first example flowchart illustrating a method of system operation during vehicle driving according to various embodiments.

FIG. 5 is a second example flowchart illustrating a method of system operation during vehicle driving according to various embodiments.

### DETAILED DESCRIPTION

Hereinafter, various embodiments of the present disclosure will be described in detail with reference to the accompanying drawings. The embodiments and terminology used herein are not intended to limit the technical scope of the present disclosure to the specific forms described, but should be understood to include various modifications, equivalents, and/or alternatives thereof.

In the description of the drawings, like reference numerals may denote similar components. Unless clearly indicated otherwise in the context, the singular expressions may include plural forms. In the present disclosure, expressions such as “A or B” or “at least one of A and/or B” may include all possible combinations of the listed items.

Terms such as “first,” “second,” “primary,” or “secondary” may be used to describe components for the sake of distinction and do not imply any particular order or importance. For example, the term “first component” may be used merely to distinguish it from a “second component.”

When a component (e.g., a first component) is described as being “connected to” or “coupled to” another component (e.g., a second component), it should be understood that the first component may be directly connected to the second component or indirectly connected via another component (e.g., a third component), either functionally or communicatively.

In the present disclosure, the term “configured to (or set to)” may be used interchangeably with phrases such as “adapted to,” “capable of,” “modified to,” “made to,” “able to,” or “designed to,” depending on the context. In some cases, the expression “a device configured to” may indicate that the device, in conjunction with other devices or components, is capable of performing a specified function.

For example, the phrase “a processor configured (or set) to perform A, B, and C” may refer to a dedicated processor (e.g., an embedded processor) for performing such operations, or a general-purpose processor (e.g., a CPU or application processor) that can execute one or more software programs stored in a memory device to perform such operations.

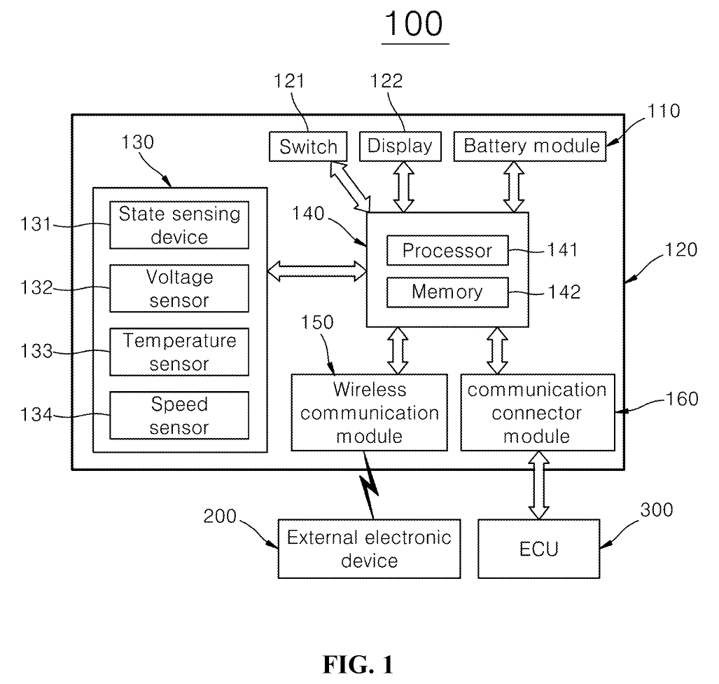

FIG. 1 is a block diagram illustrating the diagnostic structure for a battery module installed in a vehicle according to various embodiments of the present invention.

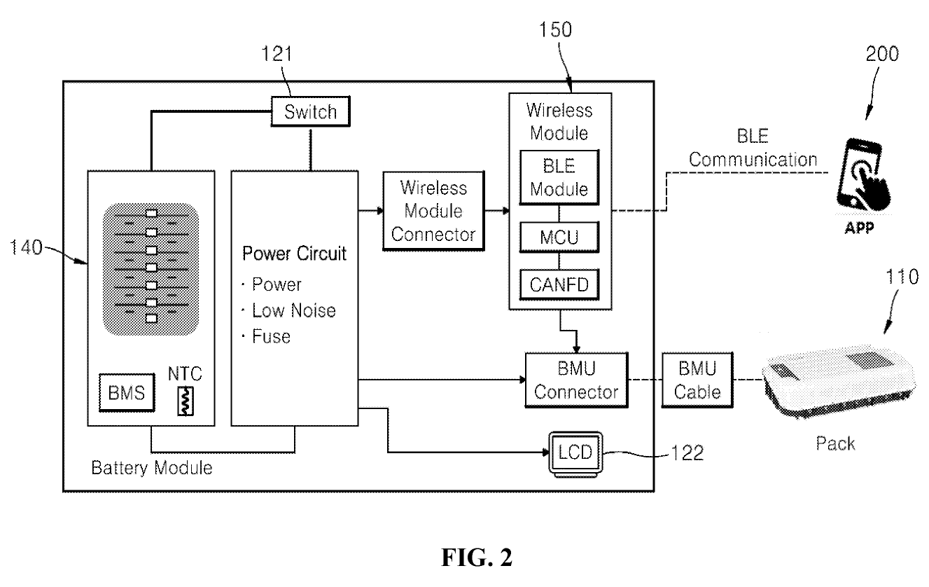

FIG. 2 is an overall view illustrating the battery module installed in a vehicle according to various embodiments of the present invention.

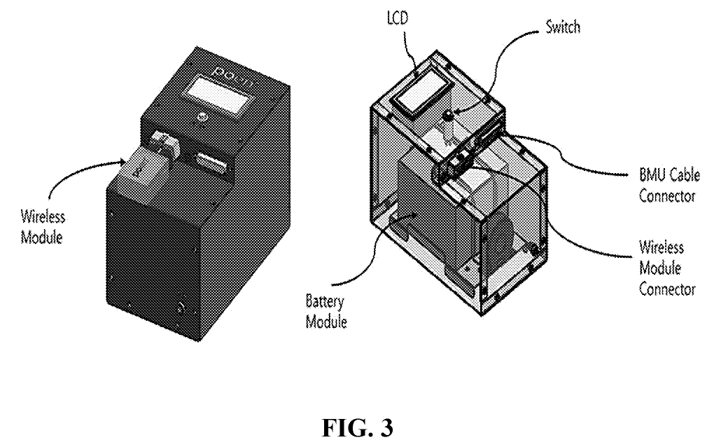

FIG. 3 is a structural diagram illustrating an example of the battery module installed in a vehicle according to various embodiments of the present invention.

According to the present embodiment, the vehicle battery pack diagnostic system (100) may include a battery module (110), a housing (120), at least one sensing module (130), a battery management system module (140), a wireless communication module (150), and a communication connector module (160).

As illustrated in FIGS. 1 to 3, the vehicle battery pack diagnostic system (100) extracts a battery pack (110) used in an electric vehicle, receives a command from an external electronic device (200), and communicates with the vehicle battery through a CAN or CANFD communication protocol. Through this communication, the system can receive information such as the State of Charge (SOC), State of Health (SOH), cell voltage, pack voltage, temperature, and driving history from the electric vehicle, and transmit the corresponding data to the external electronic device (200) and the ECU (300). This embodiment simplifies battery inspection tasks and maximizes operational efficiency.

As illustrated in FIGS. 1 to 3, the battery module (110) is installed inside an electric vehicle and includes at least one battery. The battery module (110) may be configured as a battery assembly in which multiple battery cells (not shown) are grouped in a predetermined number and enclosed within a frame to protect them from external impact, heat, and vibration. The battery module (110) may consist of a plurality of cells connected in series and/or in parallel, embedded within a mechanical structure.

In the case of the present embodiment, the electric vehicle is a scrapped vehicle, and the battery module (110) may be extracted from the scrapped vehicle and coupled to the battery pack diagnostic system (100), as illustrated in FIG. 3, to determine whether the module can be charged and reused.

As illustrated in FIGS. 1 to 3, the housing (120) accommodates the battery module (110) and may include a switch (121) and a display (123) on its upper outer surface. The housing (120) serves as the main structural frame of the vehicle battery pack diagnostic system (100), allowing installation of battery modules (110) extracted from scrapped or conventional vehicles. It may also include external coupling structures for easy verification and connection of the wireless communication module (150) and the communication connector module (160). Furthermore, the housing (120) may be electrically connected to the battery management system module (140) to operate the entire diagnostic system.

As illustrated in FIG. 3, the switch (121) may be implemented in the form of a button structure and may be configured to display output on the display (122). However, the implementation method is not limited thereto, and various other configurations are also possible.

As an example, the display (122) may include a liquid crystal display (LCD), a light-emitting diode (LED) display, an organic light-emitting diode (OLED) display, a micro-electromechanical system (MEMS) display, or an electronic paper display. The display (122) may, for example, present various types of content to the user, such as text, images, videos, icons, and/or symbols. The display (122) may include a touch screen capable of receiving input through touch, gestures, proximity, or hovering using, for example, an electronic pen or a part of the user’s body.

As illustrated in FIG. 1, the at least one sensing module (130) may be installed inside the housing (120) to detect the state of the battery module (110). The sensing module (130) may include a state sensor (131), a voltmeter (132), a temperature sensor (133), and a speed sensor (134).

For example, the state sensor (131) may detect the State of Charge (SOC) and the State of Health (SOH) of the battery module (110). The state sensor (131) may also detect the general condition of the battery, such as charge/discharge status, internal resistance, and shock detection. By measuring the internal resistance of the battery module (110), the state sensor (131) can determine performance degradation, predict the remaining life of the battery module (110) based on charge/discharge cycles and patterns, and detect external shocks or vibrations applied to the battery module (110) to determine potential damage.

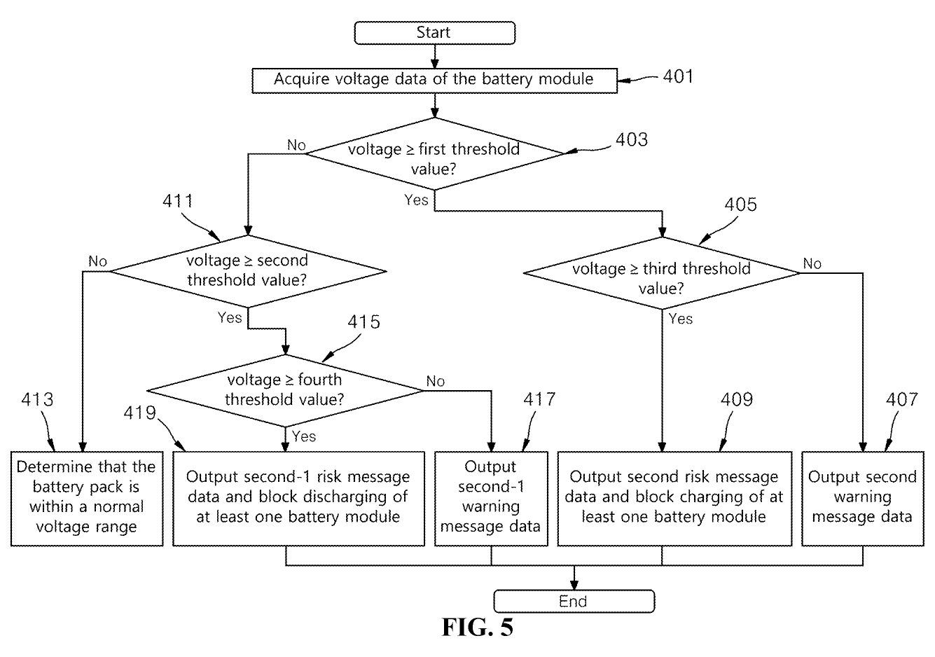

The voltmeter (132) may measure the voltage of the battery and the battery module (110) to detect any voltage abnormalities. Additionally, it may measure the voltage of each cell and/or battery module (110) to determine imbalance, predict potential battery damage when the voltage rises above or falls below a certain threshold, perform protective actions, and analyze voltage fluctuation patterns to optimize charge/discharge efficiency. A detailed operating method based on the voltmeter (132) will be described later with reference to FIG. 5.

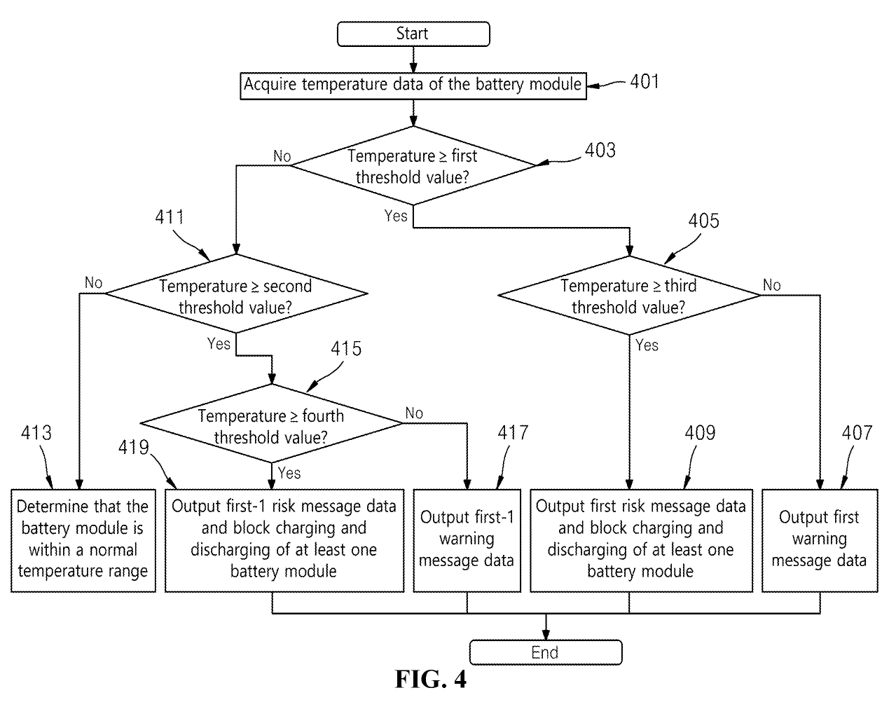

The temperature sensor (133) may detect the temperature of the battery module (110) to prevent overheating and optimize thermal management. It may monitor the operating temperature of the battery module (110) in real time and activate a cooling system when a certain temperature threshold is exceeded. In cases of localized overheating, the sensor may initiate protective actions such as stopping usage or adjusting power output, and detect performance degradation due to external temperature variations. A detailed operation method based on the temperature sensor (133) will be described later with reference to FIG. 4.

The speed sensor (134) may measure driving history values and speeds related to the battery module (110), such as vehicle travel speed or charge/discharge rate. Furthermore, the speed sensor (134) may analyze the correlation between the movement speed of the device using the battery module (110) (e.g., an electric vehicle) and battery consumption to support efficient energy management. It may also measure the charge/discharge rate of the battery module (110) to prevent overvoltage or overheating during fast charging and indirectly detect the rate of chemical reactions inside the battery module (110) to assess potential performance degradation.

As illustrated in FIGS. 1 to 3, the battery management system (BMS) module (140) may be installed inside the housing (120) and configured to communicate with the vehicle ECU (300) (Electronic Control Unit) through a CAN (Controller Area Network) protocol. The BMS module (140) may also communicate with the wireless communication module (150), the communication connector module (160), and an external electronic device (200).

For example, the battery management system module (140) may measure the current, voltage, and temperature of the battery module (110) coupled to the housing (120) based on a camera module and other sensor modules (not shown), and control the system to maintain the performance of the battery module (110). In addition, the BMS module (140) may efficiently manage the battery module (110) so that the electric vehicle equipped with the module can operate stably, predict the optimal battery replacement period (based on performance, capacity, and lifespan), and detect abnormal conditions in advance to prevent vehicle accidents.

Furthermore, the BMS module (140) may transmit various state data signals of the battery module (110) to the vehicle ECU (300)—which serves as the main vehicle control unit—through CAN communication, and may also receive various control signals for the battery module (110) via CAN communication from the ECU (300). The BMS module (140) may further transmit control data received from the ECU (300) to the first and second wireless communication modules through Bluetooth communication (100b).

The BMS module (140) may also obtain information such as the State of Charge (SOC), State of Health (SOH), cell voltage, pack voltage, temperature, and driving history of the battery module (110) based on a sensing module (not shown) installed on the side of the battery module (110).

Additionally, the BMS module (140) may include a memory (142) and a processor (141). When the temperature data of the battery module (110) exceeds a preset first temperature threshold, the BMS module (140) may output a first warning message related to charging of the battery module. When the voltage data of the battery module (110) exceeds a preset first voltage threshold, the module may output a second warning message related to charging. The operational details of these processes are described with reference to FIGS. 4 and 5.

The processor (141) may include one or more of a central processing unit (CPU), an application processor, or a communication processor (CP). The processor (141) may perform operations or data processing related to control and/or communication of at least one component of the battery module (110). For instance, the processor (141) may acquire and record data of the battery module (110), store the acquired and recorded data in the memory (142), and transmit or receive information to and from the BMS module (140) using the wireless communication module (150) and the communication connector module (160).

The memory (142) may include volatile and/or non-volatile memory. For example, the memory (142) may store commands or data related to at least one other component of the battery module (110). In one embodiment, the memory (142) may store software and/or programs. Furthermore, the memory (142) may store usage data and status logs of the battery module (110). The usage data may include information for tracking the operation history and analyzing the state of the battery module (110).

As an example, the wireless communication module (150) may be movably coupled to one end of the upper portion of the housing (120) and may include functions for receiving external control signals for the battery management system module (140) and transmitting management data of the battery management system module (140) to an external device. The wireless communication module (150) may communicate via a short-range wireless communication method based on BLE (Bluetooth Low Energy).

Here, the wireless communication module (150) may be configured to operate within the ISM (Industrial, Scientific, and Medical) frequency band of 2400–2483.5 MHz. To avoid interference with other systems that use the upper and lower frequency edges, the effective communication band may exclude 2 MHz above 2400 MHz and 3.5 MHz below 2483.5 MHz, resulting in an operational range of 2402–2480 MHz with a total of 79 available channels. To prevent mutual interference between channels, frequency hopping may be applied.

In this context, “ISM” refers to frequency bands allocated for industrial, scientific, and medical applications that do not require licensing for radio use. These bands are commonly used for personal radio, amateur radio, wireless LAN, and Bluetooth communication. “Frequency hopping” refers to a technique in which a large number of channels are rapidly switched according to a specific pattern while transmitting packets in small segments.

The wireless communication module (150) may perform frequency hopping up to 1,600 times per second across the 79 allocated channels. Communication can be established only when the hopping pattern is synchronized between Bluetooth devices. Based on this configuration, the wireless communication module (150) can perform communication between the battery module (110) and the battery pack control system module (120).

As illustrated in FIGS. 1 to 3, the communication connector module (160) may be connected to the opposite end of the upper portion of the housing (120) and configured to perform CAN (Controller Area Network) communication with the wireless communication module (150) and the vehicle ECU (Electronic Control Unit) (300).

The battery management system (BMS) module (140) may perform encryption and decryption of at least one output data set using a preset symmetric key. The communication connector module (160) may compare the checksum and sequence number included in the data frame of the encrypted and decrypted output data received through the wireless communication module (150) with a preset error threshold. If the output data exceeds the error threshold, it may be determined to be erroneous.

Specifically, the BMS module (140) may additionally generate third message data in addition to the first and/or second message data under normal operation. Thereafter, the BMS module (140) may encrypt and decrypt at least one combined output data including the first, second, and/or third message data.

The encryption and decryption of data may be implemented using one or more of the following:

### Symmetric Key Encryption:

Encryption and decryption are performed using a single key, providing high speed and efficiency. Common methods include AES (Advanced Encryption Standard) and 3DES (Triple Data Encryption Standard), an enhanced version of the now-outdated DES (Data Encryption Standard).

### Asymmetric Key Encryption:

Utilizes a public key and a private key for encryption and decryption. It provides strong security and simplified key distribution. Common methods include RSA (Rivest–Shamir–Adleman), ECC (Elliptic Curve Cryptography), which offers higher security with shorter key lengths than RSA, and the Diffie–Hellman (DH) protocol for secure key exchange.

### Hash Function:

Converts an input value into a fixed-length hash value and is useful for verifying data integrity because it cannot be decrypted. Examples include SHA algorithms (e.g., SHA-256, SHA-512) known for strong security, and the older MD5 (Message Digest Algorithm 5), which is now considered insecure.

### Quantum Cryptography:

Uses quantum mechanical principles to achieve virtually unbreakable encryption. A notable example is Quantum Key Distribution (QKD), which enables highly secure key exchange using quantum physics.

In the present embodiment, the BMS module (140) may be configured using at least one or a combination of symmetric key encryption, asymmetric key encryption, hash function, and quantum cryptography.

After encryption and decryption, the communication connector module (160) compares the checksum and sequence number in the data frame of the received output data with the preset error threshold. If the data exceeds the threshold, it is determined to contain an error.

The error threshold is used to verify both data integrity and sequence order. Specifically, the communication connector module (160) may generate a checksum for each data frame (e.g., using CRC, MD5, SHA, or XOR), include the generated checksum in a designated field of the data frame before transmission, upon receiving data, extract the checksum field and compute a new checksum using the same algorithm, compare the received checksum with the newly computed one. If the two checksums are identical, the data is considered valid. If they differ, the output data is determined to contain an error.

In addition, the communication connector module (160) may assign consecutive sequence numbers (e.g., 0, 1, 2, 3, …) to each data frame to ensure proper reassembly by the receiver. The module checks whether the received sequence number is exactly one greater than the previous frame number. If the order is correct, the data is considered valid. If not, a retransmission may be requested. Thus, the error threshold serves as a reference criterion for determining both the integrity of the checksum and the correct sequencing of received frames.

The communication connector module (160) may repeatedly retransmit output data to the BMS module (140) until the error threshold is no longer exceeded. Once at least one output data set meets the normal criteria, the module transmits the validated output data to the external electronic device (200). Furthermore, the communication connector module (160) of the present invention may be configured as a detachable module connector.

According to various embodiments of the present disclosure, the external electronic device (200) may include at least one of a smartphone, tablet PC, desktop PC, laptop PC, netbook computer, workstation, or server. The external electronic device (200) may receive various state data signals of the battery module (110), detected by the battery management system (BMS) module (140), through the communication connector module (160), and may transmit external commands to the ECU (300) based on the received information.

According to the present embodiment, the battery pack diagnostic system (100) can detect the condition and real-time charging status of the battery module (110) — which has been separated from a scrapped electric vehicle — based on at least one sensing module (130) connected to the battery management system module (140). Based on the detected information, it can determine in advance whether the battery module (110) is reusable or if preventive measures against failure are required. Furthermore, by minimizing or replacing wired connections with wireless communication during the diagnostic process, the system can shorten inspection time, enhance portability, and prevent data loss or transmission errors caused by connection faults.

FIG. 4 is a first exemplary flowchart illustrating a method of system operation during vehicle driving according to various embodiments.

In operation 401, the battery management system (BMS) module (140) (e.g., the processor (141) of FIG. 1) acquires temperature data of the battery module (110). In one embodiment, the BMS module (140) may obtain the temperature data of the battery module (110) by being connected to the temperature sensor (133). Subsequently, the BMS module (140) compares the acquired temperature data with a preset first temperature threshold.

In operation 403, the battery management system (BMS) module (140) (e.g., the processor (141) of FIG. 1) determines whether the temperature data exceeds a preset first temperature threshold. In one embodiment, the BMS module (140) may use this as a basic setting to limit the operation of the battery module (110) when the temperature increases due to heat energy generated during operation of the electric vehicle and/or general vehicle. The first temperature threshold may be configured as a warning-level value for the temperature of the battery module (110). For example, this threshold may be set to 40°C, but may be adjustable within the range of 38°C to 42°C depending on the administrator’s configuration. Subsequently, the BMS module (140) compares the measured temperature data with the administrator-defined first temperature threshold.

In operation 405, if the BMS module (140) (e.g., the processor (141) of FIG. 1) determines that the temperature data exceeds the first temperature threshold, it then compares the temperature data with a second temperature threshold that is set higher than the first threshold. In one embodiment, if the BMS module (140) detects that the temperature of the battery module (110) is 43.1°C, it may determine that the value exceeds the first temperature threshold (e.g., 40°C). The BMS module (140) then compares this temperature with the second temperature threshold, which represents a danger-level limit. For example, the second temperature threshold may be set to 45°C, but may be configurable within the range of 43°C to 47°C by the administrator. The BMS module (140) compares the obtained temperature data against this second temperature threshold to evaluate the risk level.

In operation 407, if the BMS module (140) (e.g., the processor (141) of FIG. 1) determines that the temperature data exceeds the first temperature threshold but does not exceed the second temperature threshold, it outputs a first warning message data. For instance, if the BMS module (140) detects a temperature value of 42.4°C, it determines that the value exceeds the first temperature threshold (e.g., 40°C) but does not exceed the second threshold (e.g., 45°C). In this case, the BMS module (140) recognizes that the temperature should be reduced, although it is not yet at a dangerous level, and therefore outputs a first warning message data.

Subsequently, the BMS module (140) drives at least one output module (150) so that the display (122) included therein presents the first warning message data. Furthermore, the BMS module (140) may transmit the first warning message data to the external electronic device (200) through the communication connector module (160), allowing the user and/or administrator to check the warning message in real time.

Meanwhile, in operation 405, if the battery management system (BMS) module (140) (e.g., the processor (141) of FIG. 1) determines that the temperature data exceeds both the first and second temperature thresholds, then in operation 409, the BMS module (140) may output first danger message data, which indicates a more critical status than the first warning message, and may cut off charging of the battery module (110) through at least one output module (150).

In one embodiment, the BMS module (140) may detect that the temperature of the battery module (110) has reached 46.8 °C, thereby determining that it exceeds both the first temperature threshold (e.g., 40 °C) and the second temperature threshold (e.g., 45 °C). The BMS module (140) then judges that the temperature level is dangerous and outputs first danger message data corresponding to a more severe stage than the first warning message.

Furthermore, the BMS module (140) may drive the switch (121) included in at least one output module (150) to stop the charging and discharging of the battery module (110). It may also display the first danger message data on the display (122) included in at least one output module (150), and transmit the same to the external electronic device (200) via the communication connector module (160) so that the user and/or administrator can be alerted to the danger status in real time.

Meanwhile, in operation 403, if the BMS module (140) (e.g., the processor (141) of FIG. 1) determines that the temperature data does not exceed the first temperature threshold, then in operation 411, the BMS module (140) determines whether the temperature data is equal to or higher than a third temperature threshold, which is set below the first temperature threshold.

In one embodiment, if the temperature value of the battery module (110) is detected as 23.9 °C, the BMS module (140) determines that it does not exceed the first temperature threshold (e.g., 40 °C). Thereafter, the BMS module (140) compares the temperature data with the third temperature threshold, which is set to represent a low-temperature warning condition.

The third temperature threshold may be configured inversely to the first threshold, serving as a criterion for abnormally low temperature. For example, the third temperature threshold may be set to 5 °C, and may be adjustable between 3 °C and 7 °C depending on administrator settings. The BMS module (140) then compares the temperature data based on the administrator-defined third temperature threshold to determine whether the battery module (110) is operating under a low-temperature risk condition.

In operation 413, the battery management system (BMS) module (140) (e.g., the processor (141) of FIG. 1) determines that the battery module (110) is operating at a normal temperature when the temperature data is equal to or higher than the third temperature threshold.

For example, if the BMS module (140) detects a temperature of 32.6 °C, it determines that the value does not exceed the first temperature threshold (e.g., 40 °C) but is above the third temperature threshold (e.g., 5 °C). The BMS module (140) therefore recognizes that the temperature of the battery module (110) is within the normal operating range. The system may then repeatedly perform operation 401 until the temperature data exceeds either the first or third temperature threshold.

Meanwhile, in operation 411, if the BMS module (140) determines that the temperature data is equal to or below the third temperature threshold, then in operation 415, the BMS module (140) compares the temperature data with a fourth temperature threshold, which is set below the third threshold.

For instance, if the temperature value detected from the battery module (110) is 2.7 °C, the BMS module (140) determines that it is below the third temperature threshold (e.g., 5 °C). The system then compares this value with the fourth temperature threshold, which indicates a danger-level condition at low temperatures. The fourth temperature threshold may, for example, be 0 °C, and may be adjustable within the range of –2 °C to +2 °C according to administrator settings. The BMS module (140) then compares the temperature data based on the administrator-defined fourth temperature threshold.

In operation 417, if the BMS module (140) determines that the temperature data is below the third temperature threshold but above the fourth temperature threshold, it outputs a first-1 warning message data through at least one output module (150).

For example, if the temperature of the battery module (110) is detected as 2.8 °C, the BMS module (140) determines that the value is below the third temperature threshold (e.g., 5 °C) but above the fourth temperature threshold (e.g., 0 °C). In this case, it concludes that the temperature should be increased, though the situation is not critical, and outputs the first-1 warning message data.

The BMS module (140) then drives the display (122) included in at least one output module (150) to show the first-1 warning message data. The message may also be transmitted to the external electronic device (200) via the communication connector module (160), allowing the user and/or administrator to view the alert in real time.

Meanwhile, in operation 415, if the BMS module (140) determines that the temperature data is equal to or below both the third and fourth temperature thresholds, then in operation 419, the BMS module (140) outputs a first-1 danger message data, which represents a more severe stage than the first-1 warning message, and cuts off charging and discharging of the battery module (110).

For example, if the temperature value detected from the battery module (110) is –3.3 °C, the BMS module (140) determines that it is below both the third temperature threshold (e.g., 5 °C) and the fourth temperature threshold (e.g., 0 °C). It then determines that the battery module (110) is in a dangerous low-temperature condition and outputs the first-1 danger message data, corresponding to a more critical level than the first-1 warning message.

The BMS module (140) drives the switch (121) included in at least one output module (150) to block charging and discharging of the battery module (110). It also drives the display (122) to present the first-1 danger message data and transmits the same information to the external electronic device (200) via the communication connector module (160) so that the user and/or administrator can immediately confirm the low-temperature danger status.

According to the present embodiment, the battery management system (BMS) module (140) verifies the temperature data measured by the temperature sensor (133) of the battery module (110) based on each preset threshold value. Thus, when the temperature of the battery module (110) becomes excessively low or high, the BMS module (140) can not only notify external and/or internal users of a warning and/or danger status but also automatically regulate the temperature, providing a significant operational advantage.

FIG. 5 is a second exemplary flowchart illustrating a method of system operation during vehicle driving according to various embodiments.

In operation 501, the battery management system (BMS) module (140) (e.g., the processor (141) of FIG. 1) acquires voltage data of the battery module (110). In one embodiment, the BMS module (140) may obtain the voltage data of the battery module (110) by being connected to the voltmeter (132). After acquiring the voltage data, the BMS module (140) compares the obtained voltage data with a first voltage threshold.

In operation 503, the BMS module (140) (e.g., the processor (141) of FIG. 1) determines whether the voltage data exceeds the preset first voltage threshold. In one embodiment, since the battery module (110) may experience an increase in voltage due to power energy generated during operation of an electric or general vehicle, the BMS module (140) may use this as a basic configuration to restrict the usage of the battery module (110) when excessive voltage increases are detected.

The first voltage threshold may represent a warning-level voltage for the battery module (110). For example, this value may be set to 4.15 V, and it may be adjustable within the range of 4.13 V to 4.17 V depending on administrator configuration. Thereafter, the BMS module (140) compares the measured voltage data with the administrator-defined first voltage threshold.

In operation 505, the battery management system (BMS) module (140) (e.g., the processor (141) of FIG. 1) determines whether the voltage data exceeds the first voltage threshold, and if so, compares the voltage data with a second voltage threshold that is set higher than the first.

For example, if the BMS module (140) detects a voltage value of 4.17 V from the battery module (110), it determines that the value exceeds the first voltage threshold (e.g., 4.15 V). The BMS module (140) then compares the measured voltage with the second voltage threshold, which represents a danger-level condition for the battery module (110). The second voltage threshold may be set to 4.20 V, and may be adjustable within the range of 4.18 V to 4.22 V according to administrator configuration. The BMS module (140) compares the voltage data based on this administrator-defined second voltage threshold to evaluate the level of risk.

In operation 507, if the BMS module (140) (e.g., the processor (141) of FIG. 1) determines that the voltage data exceeds the first voltage threshold but does not exceed the second voltage threshold, it outputs a second warning message data.

For instance, if the BMS module (140) detects a voltage value of 4.19 V from the battery module (110), it determines that the value exceeds the first voltage threshold (e.g., 4.15 V) but remains below the second voltage threshold (e.g., 4.20 V). In this situation, the BMS module (140) recognizes that the battery module (110) voltage needs to be reduced, although the condition is not yet dangerous, and thus outputs a second warning message data.

The BMS module (140) may then drive the display (122) included in at least one output module (150) to show the second warning message data. Furthermore, it may transmit the second warning message data to the external electronic device (200) through the communication connector module (160), allowing the user and/or administrator to check the alert in real time.

Meanwhile, in operation 505, if the battery management system (BMS) module (140) (e.g., the processor (141) of FIG. 1) determines that the voltage data exceeds both the first and second voltage thresholds, then in operation 509, the BMS module (140) outputs a second danger message data, which represents a more severe condition than the second warning message, and blocks the charging process of the battery module (110) through at least one output module (150).

For example, if the BMS module (140) detects a voltage value of 4.24 V from the battery module (110), it determines that this value exceeds both the first voltage threshold (e.g., 4.15 V) and the second voltage threshold (e.g., 4.20 V). The BMS module (140) then recognizes that the voltage level is dangerous and outputs a second danger message data indicating a critical condition.

The BMS module (140) may drive the switch (121) included in at least one output module (150) to block the charging of the battery module (110). In addition, it may display the second danger message data on the display (122) of the output module (150), and transmit the same message through the communication connector module (160) to the external electronic device (200) so that the user and/or administrator can immediately check the danger alert.

Meanwhile, in operation 503, if the BMS module (140) (e.g., the processor (141) of FIG. 1) determines that the voltage data does not exceed the first voltage threshold, then in operation 511, the BMS module (140) determines whether the voltage data is equal to or higher than a third voltage threshold, which is set below the first voltage threshold.

For instance, if the voltage data of the battery module (110) is detected as 3.91 V, the BMS module (140) determines that the value does not exceed the first voltage threshold (e.g., 4.15 V). The system then compares the voltage data with the third voltage threshold, which represents a low-voltage warning level.

The third voltage threshold may be set as the opposite of the first threshold, serving as a reference for undervoltage conditions. For example, the third voltage threshold may be configured to 3.15 V, and may be adjustable within the range of 3.13 V to 3.17 V depending on administrator configuration. The BMS module (140) then compares the voltage data based on the administrator-defined third voltage threshold to determine whether the battery module (110) is approaching a low-voltage warning condition.

In operation 513, the battery management system (BMS) module (140) (e.g., the processor (141) of FIG. 1) determines that the battery module (110) is operating at a normal voltage when the voltage data is equal to or higher than the third voltage threshold.

For example, if the BMS module (140) detects a voltage value of 3.66 V, it determines that the value does not exceed the first voltage threshold (e.g., 4.15 V) but remains above the third voltage threshold (e.g., 3.15 V). Thus, the BMS module (140) recognizes the voltage of the battery module (110) as normal. The system may repeatedly perform operation 501 until the voltage data exceeds either the first or third voltage threshold.

Meanwhile, in operation 511, if the BMS module (140) determines that the voltage data is equal to or below the third voltage threshold, then in operation 515, the BMS module (140) compares the voltage data with a fourth voltage threshold, which is set below the third threshold.

For example, if the BMS module (140) detects a voltage value of 3.11 V, it determines that the value is below the third voltage threshold (e.g., 3.15 V). The module then compares this value with the fourth voltage threshold, which indicates a danger-level low voltage. The fourth voltage threshold may be set to 3.00 V, and may be adjustable within the range of 2.98 V to 3.02 V according to administrator settings. The BMS module (140) compares the voltage data based on this administrator-defined fourth voltage threshold.

In operation 517, if the BMS module (140) determines that the voltage data is below the third voltage threshold but above the fourth voltage threshold, it outputs a second-1 warning message data through at least one output module (150).

For instance, if the detected voltage of the battery module (110) is 3.09 V, the BMS module (140) determines that it is below the third voltage threshold (e.g., 3.15 V) but above the fourth voltage threshold (e.g., 3.00 V). In this situation, the BMS module (140) concludes that the voltage should be increased, although the condition is not yet dangerous, and outputs the second-1 warning message data.

The BMS module (140) may drive the display (122) included in at least one output module (150) to show the second-1 warning message data. It may also transmit this message to the external electronic device (200) through the communication connector module (160) so that the user and/or administrator can view the warning in real time.

Meanwhile, in operation 515, if the BMS module (140) determines that the voltage data is equal to or below both the third and fourth voltage thresholds, then in operation 519, the BMS module (140) outputs a second-1 danger message data, representing a more severe stage than the second-1 warning message, and blocks discharging of the battery module (110).

For example, if the voltage value detected from the battery module (110) is 2.93 V, the BMS module (140) determines that it is below both the third voltage threshold (e.g., 3.15 V) and the fourth voltage threshold (e.g., 3.00 V). The module then determines that the voltage level is dangerously low and outputs the second-1 danger message data corresponding to a critical low-voltage condition.

The BMS module (140) drives the switch (121) included in at least one output module (150) to stop discharging of the battery module (110). It may also display the second-1 danger message data on the display (122) and transmit the same to the external electronic device (200) through the communication connector module (160) so that the user and/or administrator can promptly identify the low-voltage danger status.

According to the present embodiment, the battery management system (BMS) module (140) verifies the voltage data measured by the voltmeter (132) of the battery module (110) based on each preset threshold value. Therefore, when the voltage of the battery module (110) becomes excessively low or high, the BMS module (140) not only alerts external and/or internal users to the warning or danger state but also automatically adjusts the system accordingly. This provides an advantage of autonomous protection and enhanced stability of the battery system.

In addition, the BMS module (140) may simultaneously receive temperature data and/or voltage data and respond dynamically according to each corresponding threshold, enabling integrated management of both parameters to ensure safe operation.

In the present disclosure, the terms “module” or “unit” refer to components that may be implemented in hardware, software, or firmware, and may be used interchangeably with terms such as logic, logic block, component, or circuit. A “module” or “unit” may be an integrated component, a minimal functional block that performs one or more functions, or a part thereof.

A “module” or “unit” may be implemented mechanically or electronically, and may include, for example, ASICs (Application-Specific Integrated Circuits), FPGAs (Field-Programmable Gate Arrays), or programmable logic devices, whether known or to be developed in the future, that perform specific operations. These modules may be executed by a processor (120).

At least a portion of a device (e.g., modules or their functions) or method (e.g., operations) according to various embodiments may be implemented as program modules in the form of instructions stored on a computer-readable storage medium (e.g., memory (130)). When executed by a processor (e.g., the processor (120)), the instructions enable the processor to perform the functions corresponding to those instructions.

The computer-readable recording medium may include, but is not limited to, a hard disk, floppy disk, magnetic medium (e.g., magnetic tape), optical recording medium (e.g., CD-ROM, DVD), magneto-optical medium (e.g., floptical disk), or embedded memory. The instructions may include code generated by a compiler or code executable by an interpreter.

Modules or program modules according to various embodiments may include at least one of the foregoing elements, omit some of them, or further include other elements. Operations performed by the modules, program modules, or other components according to various embodiments may be executed sequentially, in parallel, repetitively, or heuristically. Some operations may be executed in a different order, omitted, or supplemented with additional operations.

The embodiments disclosed herein are presented for the purpose of explaining and understanding the disclosed technical contents and are not intended to limit the scope of the present disclosure. Accordingly, the scope of the present disclosure should be construed to include all modifications and various alternative embodiments based on the technical spirit of the disclosure.

What is claimed is:

1. A vehicle battery pack diagnostic system, comprising:
a battery module installed inside an electric vehicle and including at least one battery therein;
a housing that accommodates the battery module and includes a switch and a display on an upper outer surface thereof;
at least one sensing module installed inside the housing and configured to detect a status of the battery module;
a battery management system (BMS) module installed inside the housing and configured to:
output first warning message data related to charging of the battery module when temperature data of the battery module detected by the at least one sensing module exceeds a preset first temperature threshold, and
output second warning message data related to charging of the battery module when voltage data of the battery module detected by the at least one sensing module exceeds a preset first voltage threshold;
a wireless communication module movably coupled to one end of the upper portion of the housing, configured to receive an external control signal for the battery management system module, transmit management data of the battery management system module to an external device, and communicate through a Bluetooth Low Energy (BLE) short-range wireless communication method; and
a communication connector module connected to the other end of the upper portion of the housing and configured to enable Controller Area Network (CAN) communication between the battery management system module and a vehicle electronic control unit (ECU).

2. The system of claim 1, wherein the at least one sensing module comprises:
a state sensor configured to detect a State of Charge (SOC) and a State of Health (SOH) of the battery module;
a voltmeter configured to detect a voltage of the battery and the battery module;
a temperature sensor configured to detect a temperature of the battery module; and
a speed sensor configured to detect a driving history value of the battery module.

3. The system of claim 1, wherein the battery management system module is configured such that:
when temperature data of the battery module is determined to be equal to or higher than a first temperature threshold and equal to or lower than a second temperature threshold that is greater than the first threshold, the module outputs first warning message data; and
when the temperature data of the battery module is determined to be equal to or higher than both the first and second temperature thresholds, the module outputs, through at least one output module, first danger message data set to a more critical level than the first warning message data, and blocks charging of the battery module.

4. The system of claim 3, wherein the battery management system module is configured such that:
when temperature data of the battery module is determined to be equal to or lower than a third temperature threshold, which is set below the first temperature threshold, and equal to or higher than a fourth temperature threshold, which is set below the third temperature threshold, the module outputs first-1 warning message data through at least one output module; and
when the temperature data of the battery module is determined to be equal to or lower than both the third and fourth temperature thresholds, the module outputs first-1 danger message data, set to a more critical level than the first-1 warning message data, through at least one output module while blocking charging and discharging of the battery module.

5. The system of claim 1, wherein the battery management system module is configured such that:
when voltage data of the battery module is determined to be equal to or higher than a first voltage threshold and equal to or lower than a second voltage threshold that is greater than the first voltage threshold, the module outputs second warning message data through at least one output module; and
when the voltage data of the battery module is determined to be equal to or higher than both the first and second voltage thresholds, the module outputs, through at least one output module, second danger message data set to a more critical level than the second warning message data, and blocks charging of the battery module.

6. The system of claim 5, wherein the battery management system module is configured such that:
when voltage data of the battery module is determined to be equal to or lower than a third voltage threshold, which is set below the first voltage threshold, and equal to or higher than a fourth voltage threshold, which is set below the third voltage threshold, the module outputs second-1 warning message data through at least one output module; and
when the voltage data of the battery module is determined to be equal to or lower than both the third and fourth voltage thresholds, the module outputs, through at least one output module, second-1 danger message data set to a more critical level than the second-1 warning message data, and blocks both charging and discharging of the battery module.

7. The system of claim 1, wherein the battery management system module performs encryption and decryption of at least one output data using a preset symmetric key, and
the communication connector module is configured to:
compare a checksum and a sequence number included in a data frame of the encrypted and decrypted output data received through the wireless communication module with a preset error threshold, and
determine that the output data is composed of an error value when the comparison result exceeds the error threshold.
